(19) United States
(12) Patent Application Publication
(10) Pub. No.: US 2022/0003675 A1
(43) Pub. Date: Jan. 6, 2022

(54) METHOD AND DEVICE FOR SIMULATING THE VISIBILITY OF A PAINT FOR A LIDAR SENSOR, WHICH PAINT IS APPLIED TO A SURFACE

(71) Applicant: BASF Coatings GmbH, Münster (DE)

(72) Inventors: Thomas Kantimm, Muenster (DE); Benjamin Lanfer, Muenster (DE); Alfred Wolcke, Muenster (DE); Markus Mundus, Muenster (DE)

(21) Appl. No.: 17/293,036

(22) PCT Filed: Nov. 15, 2019
(86) PCT No.: PCT/EP2019/081501

§ 371 Date: May 11, 2021

(30) Foreign Application Priority Data
Nov. 15, 2018 (EP) 18206542.5

(51) Int. Cl. G01N 21/57; G01S 17/931; G01N 21/84; G06F 30/20

(52) U.S. Cl. CPC G01N 21/57; G01S 17/931; G01N 2021/575; G06F 30/20; G01N 2021/8427; G01N 21/8422

(57) ABSTRACT

Described herein is a method for simulating a visibility of a coating applied on a surface for a LiDAR sensor, which includes at least the following steps:
applying the coating on the surface (301);
measuring a respective reflection of light having an operating wavelength of the LiDAR sensor from the surface coated with the coating at a multiplicity of illumination and/or measurement angles (302);
adapting a bidirectional reflectance distribution function for the coating as a function of the respective illumination and/or measurement angle to the respective measured reflections (303);
simulating a propagation of the light emitted by the LiDAR sensor and reflected by the surface coated with the coating on the basis of the adapted bidirectional reflectance distribution function by means of a ray tracing application (304);
outputting a brightness image.

The present invention relates to a method and to a corresponding device for simulating a visibility of a coating applied on a surface for a LiDAR sensor.

For the development of autonomous vehicles and modern driver assistance systems, there are a multiplicity of sensors which are required in order to make it possible to have certain functionalities, which have previously been carried out manually, in particular by a driver, performed automatically. One type of sensor which can deliver important, in particular spatial, information is in this context the LiDAR sensor.

For autonomous driving, LiDAR now assumes an important status. LiDAR stands for “Light Detection and Ranging”, i.e. for an optical measuring system for detecting objects. A LiDAR sensor in this case emits directional laser pulses in the infrared range. When such a laser pulse strikes an object, it is reflected, the reflected light, or the reflected laser pulse, in turn being received by the LiDAR sensor. From a time of flight of the laser pulse, starting from its emission until its reception at the LiDAR sensor, a distance from the LiDAR sensor to the object struck by the laser pulse can be calculated.

This means that by reflection of the emitted light or laser pulse at the object until incidence of the light, or the laser pulse, at the receiver, i.e. the LiDAR sensor itself, the position of the object can be determined by means of the time of flight of the light, or of the laser pulse.

However, the LiDAR sensor can measure a distance to an object only when a sufficient quantity of light is reflected back from the object in the direction of the LiDAR sensor. This means that, for a given distance of an object, the object can be detected only when the reflection, or the reflected light quantity, of the object at an operating wavelength of the LiDAR sensor is sufficiently large.

The reflection properties of a vehicle are dominated by the coating with which the vehicle or the vehicle body is coated.

In order to ensure that vehicles, particularly in traffic with autonomously driving vehicles, can be detected reliably and in a large region by the LiDAR sensor, it is desirable to evaluate and optimize a vehicle coating job of a respective vehicle in this respect.

In order to evaluate and optimize a reflection of a vehicle coating job of a respective vehicle, it is known to provide a large range of sample surfaces with a respective vehicle coating job, or coat them with a respective coating. The sample surfaces coated in this way are then tested with the aid of a LiDAR sensor positioned at a predetermined distance from the respective surfaces with respect to the visibility or detectability thereof by the LiDAR sensor. This means that the respective sample surfaces are first exposed to a light, generally a laser pulse, having an operating wavelength of the LiDAR sensor, and the light reflected back by the respective surfaces is then in turn received at the LiDAR sensor, and in particular its light quantity and/or intensity is evaluated. The reflection values resulting in this case for the various sample surfaces are compared with one another. On the basis of such a comparison, successive modifications of the respective coating jobs, or of the respective coating, are carried out in order to ultimately select an optimal coating job for the detection by the LiDAR sensor, from given coating jobs. The distance between the LiDAR sensor and the sample surfaces may in this case be varied in order to be able to emulate as many conceivable scenarios as possible, particularly in road traffic.

The terms coating job, coating, vehicle coating and vehicle coating job are used synonymously with one another in the scope of the present disclosure.

In order to make such an evaluation and optimization of the reflection of a respective coating, with which a respective vehicle is coated, as efficient as possible, it was an object of the present invention to provide a possibility of simulating and visualizing how well a vehicle would be visible for a LiDAR sensor if the vehicle is or would be coated with a predetermined coating, or a predetermined coating job.

A solution to this object is provided by the features of the independent patent claims. Advantageous configurations may be found in the respective dependent claims and the description.

A method for simulating a visibility of a coating applied on a surface for a LiDAR sensor is provided. The method according to the invention comprises at least the following steps:
applying the coating on the surface;
measuring a respective reflection of light having an operating wavelength of the LiDAR sensor from the surface coated with the coating at a multiplicity of illumination and/or measurement angles;
adapting a bidirectional reflectance distribution function for the coating as a function of the respective illumination and/or measurement angle to the respective measured reflections;
simulating a propagation of the light emitted by the LiDAR sensor and reflected by the surface coated with the coating on the basis of the adapted bidirectional reflectance distribution function by means of a ray tracing application, the LiDAR sensor being simulated as a unit comprising a point light source and a camera, and the surface coated with the coating being simulated as a profile which is arranged, or can be arranged, at a variable distance with a variable orientation in front of the camera, wherein, preferably, a computer graphics model is applied to the profile by using the adapted bidirectional reflectance distribution function;
outputting a brightness image, which shows a brightness of the light reflected (in a simulated manner) by the profile in the direction of the LiDAR sensor or the unit comprising the light source and the camera, while taking into account the adapted bidirectional reflectance distribution function.

“Outputting” a brightness image in this case means that a brightness image is determined, in particular calculated, on the basis of the preceding step of the simulation, and a result derived therefrom is displayed. The displayed result may in this case be the brightness image itself or an image derived therefrom, for example an image of the visibility. A representation/display of the brightness image may be configured in various ways. For instance, regions of different brightness may be represented or displayed distinguishably from one another by means of correspondingly different patterns/shadings or different colors. Any other suitable type of representation/display may also be envisioned.

Typical operating wavelengths of a LiDAR sensor are 905 nm or 1550 nm. This means that a LiDAR sensor can only emit light of a wavelength of 905 nm or of 1550 nm, and can also only detect this (elastic backscattering).

In one possible configuration of the method according to the invention, the coating, which is produced on the basis of a coating formulation and whose visibility for the LiDAR sensor is to be studied, is applied onto a narrow flat sample surface, and is optionally also covered with a clear coat. In the subsequent method step, i.e. during the measurement of a respective reflection of light having an operating wavelength of the LiDAR sensor from the surface coated with the coating, a gonio-spectrophotometer is generally used. The measurements are carried out at a multiplicity of illumination and/or measurement angles, those measurement geometries also being included in which the illumination and the observation ormeasurement direction or angle are approximately equal.

A gonio-spectrophotometer, also referred to as a spectro-goniometer, gonioreflectometer, reflection goniometer, reflectance goniometer or for the sake of brevity apparatus for angle determination, an apparatus for measuring a reflection behavior of a surface, and in particular angle-dependent properties of the surface, or of the coating with which the surface is coated, may in this case be determined.

In general, the reflectance distribution function (BRDF) for the coating is determined at respective given illumination and measurement angles relative to the surface, or to the respective sample surface, i.e. a reflection or a respective reflection value is determined as a function of the light incidence and of the sensor position, or measurement position. In this case, the azimuth angle (angular direction of the illumination, measured from a cardinal direction (in general north) at 0° in the clockwise direction up to)360° and the zenith angle (angular position of the illumination above the surface, measured from the surface (0° to))90° are taken into account as variables in the measurement geometry. The BRDF is a fundamental optical property of the reflective coating, or of the coating formulation on which the coating is based. Because of the great variability of the BRDF, according to the invention provision is made to simulate both the LiDAR sensor itself and also the surface coated with the coating, or to represent them in a model which describes the characteristic properties both of the LiDAR sensor and of the coating. In particular anisotropic reflection behavior of the light emitted by the LiDAR sensor and reflected by the surface, which is also referred to as anisotropic reflectance or differentiated spectroscopic reflectance, influences to a great extent the BRDF of the coating to be studied.

In one possible configuration, the bidirectional reflectance distribution function for the coating is formed from a weighted diffuse Lambert term and a Cook-Torrance illumination model term having at least one specular lobe. In one possible configuration of the method according to the invention, parameters of the bidirectional reflectance distribution function are optimized with respect to a cost function during the adaptation of the bidirectional reflectance distribution function for the coating to the respective measured reflections or the respective reflection values obtained by the respective measurement. This means that the parameters of the bidirectional reflectance distribution function (Lambert coefficient, weights of the Cook-Torrance specular lobe, etc.) are corrected with the aid of the measured reflections, or the photospectrometer measurement data, or the reflection values. To this end, the parameters are optimized in such a way that a distance of reflection information in the optimized model from corresponding values, or reflection values, of the measurement is minimal. Reflection information in this case comprise in particular reflection values, or brightness values.

It is conceivable that in this case, as a constraint, it is assumed that the optimized model remains similar to the original model, in order to prevent instabilities from occurring during the optimization because of a small amount of measurement data, or measurement values, and a large number of parameters in comparison therewith. It is conceivable to provide constraints which ensure that the values for the parameters remain in a reliable value range. With these conditions, it is possible to formulate a system of nonlinear minimization conditions which can be minimized with corresponding optimization methods, for example the Nelder-Mead downhill simplex method, also referred to for the sake of brevity as the downhill simplex method or Nelder-Mead method. In one configuration, the cost function is formed on the basis of a penalty term and a sum of squared differences between the measured respective reflections and respective reflections or reflection values simulated on the basis of the bidirectional reflectance distribution function.

$$C ( x ) = {\sum }_{g ∈ {G}_{M}} {( {R}_{T} ( g , x ) - {R}_{M} ( g ) )}^{2} + P ( x ) \qquad ( 1 )$$

C: cost function

g: respective measurement geometry characterized by the azimuth and zenith angles of the respective illumination and observation directions

G_{M}: set of measurement geometries, which is used for determining the BRDF

R_{T}: reflection value calculated for the current parameters with the aid of the BRDF

R_{M}: reflection value measured with the gonio-spectrophotometer

P: penalty function, or penalty term

x=(k_{D},m,R₀: vector of the parameters to be optimized

k_{D}: parameter for the weighting of the diffuse Lambert term

m: parameter of a Beckmann distribution

R₀: parameter of a Fresnel reflection

$${R}_{T} ( g , {k}_{D} , {k}_{S} , m , {R}_{0} ) = ( \frac{{k}_{D}}{π} + \frac{{k}_{S} \cdot D ( m ) \cdot F ( {R}_{0} ) \cdot G}{4 π < N , V > < N , L >} ) \cdot {F}_{CC} \qquad ( 2 )$$

k_{S}: parameter for the weighting of the specular component (Cook-Torrance specular lobe)

D(m): Beckmann distribution function

F(R₀): Fresnel reflection

G: geometrical screening term

Fcc: factor which takes into account the reflection on an (optional) clear coat layer

N,V,L: normal, observation and illumination directions, which can be derived from the respective measurement geometry g

<,>: scalar product of two vectors

$$P ( {k}_{D} , m , {R}_{0} ) = \{ \begin{matrix}p & {k}_{D} < 0 \\ 0 & else\end{matrix} + \{ \begin{matrix}p & ( m < 0 ) ⩔ ( m > 1 ) \\ 0 & else\end{matrix} + \{ \begin{matrix}p & {R}_{0} < 0 \\ 0 & else\end{matrix} \qquad ( 3 )$$

p»1: Penalty value; selected here in the application for example as p=1e3.

The Beckmann distribution describes the angle-dependent reflection of a microfacet surface. A microfacet surface is a rough specular surface which may be described in a model as a collection of small mirrors (microfacets) which are tilted with respect to the surface normal according to a certain distribution. The term Beckmann distribution is familiar in the computer graphics literature (Beckmann microfacet distribution according to Beckmann, Petr, and Andre Spizzichino. “The scattering of electromagnetic waves from rough surfaces”. Norwood, Mass., Artech House, Inc., 1987, 511 p., 1987).

The propagation of the light emitted by the LiDAR sensor and reflected by the surface coated with the coating is simulated on the basis of the adapted bidirectional reflectance distribution function by means of a ray tracing application. In this case, a commercially available ray tracing application may be used as the ray tracing application.

Ray tracing is to be understood as an algorithm, based on emission of rays, for determining a visibility of objects from a particular point in space. Ray tracing likewise refers to an extension of this basic algorithm, which calculates a further path of rays after striking a surface. In the scope of the present invention, ray tracing is in particular intended to mean such an extension, i.e. in particular calculation of a further path of the rays reflected by the surface coated with the coating after these, coming from the LiDAR sensor, have struck the surface. The ray tracing application may be carried out by an application, or app for short. In general, ray tracing operates with a data structure, namely referred to as a ray, which indicates a starting point and a direction of a half-line in space. For each pixel, a direction of the ray is calculated which points from the LiDAR sensor, or from the object, to a corresponding pixel of an image plane.

For each measurement geometry, i.e. for each illumination and/or observation or measurement angle, for the respectively coated surface a reflection value and furthermore a brightness coordinate are determined. The brightness coordinates or brightness values determined in this way for the respective measurement geometries are used during the adaptation of the bidirectional reflectance distribution function in order to be set in the cost function in relation to the modeled respective brightness values of the coating to be considered. As already mentioned above, the simulation is carried out on the basis of an operating wavelength of the LiDAR sensor. Accordingly, the BRDF describes the reflectivity of the respective coated surface for this wavelength.

The surface coated with the coating in the context of the present invention is a surface which may comprise one or more coating layers lying above one another, wherein a color-determining coating, which in the case of multilayer coatings need not constitute the top layer, constitutes that coating layer which essentially determines the intended final hue of the coated object, or of the coated surface. The top layer may, conversely, also be for example a clear coat layer.

With the gonio-spectrophotometer, reflection curves of the light emitted by the light source, optionally the LiDAR sensor, and the light reflected at the surface are determined at different observation or measurement angles. The determination of the reflection curves may be carried out with a number of different observation angles. For example, determination of five observation angles, of for example 15°, 25°, 45°, 75° and 110° relative to the specular reflection is generally sufficient. Starting from these points reflection curves for other observation angles can be determined by extrapolation. If the measurement angles, but not the illumination angles, are then modified, then for example the fixed observation angle may be 45° relative to the plane perpendicular to the surface. As an alternative thereto, it is however also conceivable to vary the observation angle, in which case a number of different observation angles may be used. In this case, it is for example conceivable to use four observation angles of, for example, 15°, 25°, 45° and 75° relative to the plane perpendicular to the surface, and to determine the reflection curves for other observation angles by extrapolation. The colorimetric data determined in this way, i.e. the reflection curves, are stored in the form of a data file with allocation to the corresponding observation and illumination angles. Optionally, the position or orientation of the surface may also be taken into account in this case.

In order to carry out the method according to the invention, the use of a conventional personal computer is generally sufficient. Of course, computers having a greater computing capacity may advantageously be used. The brightness image to be output may be generated as a visually perceptible, realistic computer image with all conventional virtual reality techniques. The brightness image may be produced in a conventional way, for example on a monitor or with the aid of a projector on a screen. For the person skilled in the art, it is clear that brightness images which are generated with the method according to the invention may be printed in the form of a visually perceptible representation on paper, or alternatively other materials. While a brightness image which exists as an encoded representation may be visually assessed, a brightness image which exists only as a file may be assessed by means of a computer. The brightness images may, for example, be evaluated with respect to desired regions, for example small as possible undetectable regions.

The method according to the invention may be used as a valuable tool in the selection of one or more coatings, or coating formulations respectively assigned thereto, in order to ensure good or sufficient visibility of a respective object coated with the respective coating, in particular of a vehicle or a vehicle body, by a LiDAR sensor, which may for example be installed on another vehicle.

According to the invention, the LiDAR sensor may be simulated as a unit comprising a point light source, which emits light beams uniformly in all directions, and a camera which records the brightness of the reflected light beams. The surface coated with the coating is simulated as a profile which is arranged at a variable distance in front of the camera with a variable orientation relative to the camera. The profile may, for example, be selected as a vehicle contour, particularly in order to take into account the case of using the LiDAR sensor in road traffic for autonomous driving, the LiDAR sensor then for example being mounted on the vehicle. By the proposed modeling of the LiDAR sensor and of the surface coated with the coating, it is for example possible to emulate a real scene in road traffic, in which a vehicle having a LiDAR sensor approaches another vehicle, which then corresponds to the object or to the surface coated with the coating.

In another configuration, a computer graphics model is provided, which is applied to the vehicle contour, or to the profile, by using the previously calculated parameters of the bidirectional reflectance distribution function, so as to represent as well as possible the reflection properties mapped with the previously adapted bidirectional reflectance distribution function, or to make them recognizable in connection with the vehicle contour or the profile.

Lastly, by the ray tracing simulation, a brightness image is output which shows a brightness of the light reflected by the profile in the direction of the LiDAR sensor while taking into account the adapted bidirectional reflectance distribution function. In one configuration how much light is reflected by different regions of the profile simulating the coated surface, in particular of the vehicle contour, is determined by means of the brightness image which has been output. In this case, it is possible to determine relatively accurately which parts of the simulated vehicle contour are invisible, which are fully visible and which are highly visible for the LiDAR sensor.

In another configuration, a brightness threshold value, which is defined by a reflected brightness of a reference template with a diffuse reflection of 10%, is applied to the brightness image which has been or is to be output. Such a reference template is normally used in order to indicate or specify a nominal region or rated region of a LiDAR sensor. The brightness image corrected or filtered in this way now shows regions of the profile, or of the vehicle contour, which are visible for a LiDAR sensor in this rated region.

It is also conceivable to output the brightness image to be output as a type of color image in which the respective brightnesses, and the reflection values associated therewith, are represented with the aid of a color scale.

In another configuration, the visible regions quantified as a percentage of a maximum visible area of the profile for a current setting of the profile relative to the camera, or to the LiDAR sensor simulated by the camera and the point light source, are indicated.

In yet another configuration, the method is carried out for a multiplicity of coatings, or of coating formulations on which the coatings are respectively based, wherein the output respective brightness images for the different coatings or coating formulations are compared with one another and that coating formulation, or that coating, which is most highly visible for the LiDAR sensor is selected from the multiplicity of coating formulations, or coatings.

The present invention furthermore relates to a system for simulating a visibility of a coating applied on a surface for a LiDAR sensor.

The system according to the invention comprises at least one spectrophotometer, preferably a gonio-spectrophotometer, which is configured for measuring a respective reflection of light having an operating wavelength of the LiDAR sensor from the surface coated with the coating at a multiplicity of illumination and/or measurement angles.

The system according to the invention furthermore comprises a computer unit, which is configured for adapting a bidirectional reflectance distribution function for the coating as a function of the respective illumination and/or measurement angle to the respective measured reflections. The system according to the invention furthermore comprises a simulation unit, which is configured for simulating a propagation of the light emitted by the LiDAR sensor and reflected by the surface coated with the coating on the basis of the adapted bidirectional reflectance distribution function by means of a ray tracing application, the LiDAR sensor being simulated as a unit comprising a point light source and a camera, and the surface coated with the coating being simulated as a profile which is arranged at a variable distance with a variable orientation in front of the camera. The point light source is in this case configured for emitting light uniformly in all directions.

In one configuration, the simulation unit comprises a computer graphics model, which is configured to be applied to the profile by using the adapted bidirectional reflectance distribution function. Lastly, the system according to the invention comprises a display unit, which is configured for outputting or displaying a brightness image on the basis of the simulated propagation of the light emitted by the LiDAR sensor and reflected by the surface coated with the coating, the brightness image showing a brightness of the light reflected by the profile in the direction of the LiDAR sensor while taking into account the adapted bidirectional reflectance distribution function.

The invention furthermore relates to a device for simulating a visibility of a coating applied on a surface for a LiDAR sensor, which comprises at least:
an application unit for applying the coating on the surface;
a measuring arrangement for measuring a respective reflection of light having an operating wavelength of the LiDAR sensor from the surface coated with the coating at a multiplicity of illumination and/or measurement angles;
a computer unit for adapting a bidirectional reflectance distribution function for the coating as a function of the respective illumination and/or measurement angle to the respective measured reflections;
a simulation unit for simulating a propagation of the light emitted by the LiDAR sensor and reflected by the surface coated with the coating on the basis of the adapted bidirectional reflectance distribution function by means of a ray tracing application, the LiDAR sensor being simulated as a unit comprising a point light source and a camera, and the surface coated with the coating being simulated as a profile which is arranged at a variable distance with a variable orientation in front of the camera;
an output unit for outputting a brightness image, which shows a brightness of the light reflected by the profile in the direction of the LiDAR sensor while taking into account the adapted bidirectional reflectance distribution function.

According to the method according to the invention, before simulating the propagation of the light emitted by a LiDAR sensor and reflected by the surface coated with the coating, a bidirectional reflectance distribution function is adapted with the aid of respective measured reflections. To this end, the coating to be considered is applied on a surface, and the surface is illuminated with light having an operating wavelength of the LiDAR sensor and measured with the aid of a measuring instrument, generally a gonio-photospectrometer, at a multiplicity of illumination and, or measurement angles. This means that a respective reflection of the emitted light, preferably of laser pulses, by the surface coated with the coating is measured at the multiplicity of illumination and/or measurement angles. The respective reflections, or reflection values, obtained in this way for the multiplicity of illumination and/or measurement angles are then used to adapt the bidirectional reflectance distribution function for the coating. This means that, with the aid of the measurement values obtained, the parameters to be determined in the bidirectional reflectance distribution function for the coating are determined by optimizing a cost function, the cost function being for example formed from a sum of squared differences between the measured reflections, or reflection values, and the modeled reflections or reflection values and a penalty term. A customary optimization method may be used for the optimization, such as for example the Nelder-Mead downhill simplex method. With the aid of the now adapted bidirectional reflectance distribution function, the propagation of the light emitted by the LiDAR sensor and reflected by the surface coated with the coating is now simulated by means of a ray tracing application. This simulation is now based on the arrangement described above.

$$C ( x ) = {\sum }_{g ∈ {G}_{M}} {( {R}_{T} ( g , x ) - {R}_{M} ( g ) )}^{2} + P ( x ) \qquad ( 1 )$$

C: cost function

g: respective measurement geometry characterized by the azimuth and zenith angles of the respective illumination and observation directions

G_{M}: set of measurement geometries, which is used for determining the BRDF

R_{T}: reflection value calculated for the current parameters with the aid of the BRDF

R_{M}: reflection value measured with the gonio-spectrophotometer

P: penalty function, or penalty term

x=(k_{D},m,R₀: vector of the parameters to be optimized

k_{D}: parameter for the weighting of the diffuse Lambert term

m: parameter of a Beckmann distribution

R₀: parameter of a Fresnel reflection

$${R}_{T} ( g , {k}_{D} , {k}_{S} , m , {R}_{0} ) = ( \frac{{k}_{D}}{π} + \frac{{k}_{S} \cdot D ( m ) \cdot F ( {R}_{0} ) \cdot G}{4 π < N , V > < N , L >} ) \cdot {F}_{CC} \qquad ( 2 )$$

k_{S}: parameter for the weighting of the specular component (Cook-Torrance specular lobe)

D(m): Beckmann distribution function

F(R₀): Fresnel reflection

G: geometrical screening term

F_{CC}: factor which takes into account the reflection on an (optional) clear coat layer

N,V,L: normal, observation and illumination directions, which can be derived from the respective measurement geometry g

<,>: scalar product of two vectors
Of Two

$$P ( {k}_{D} , m , {R}_{0} ) = \{ \begin{matrix}p & {k}_{D} < 0 \\ 0 & else\end{matrix} + \{ \begin{matrix}p & ( m < 0 ) ⩔ ( m > 1 ) \\ 0 & else\end{matrix} + \{ \begin{matrix}p & {R}_{0} < 0 \\ 0 & else\end{matrix} \qquad ( 3 )$$

p»1: Penalty value; selected here in the application for example as p=1e3.

The system according to the invention, or the device according to the invention, is in one configuration configured in order to carry out the method described above.

The present invention furthermore relates to a computer program product comprising a computer program, having program code means which are configured in order to carry out at least the computer-assisted steps of the method described above, i.e. in particular the adaptation step, the simulation step and the output step, when the computer program is run on a computer unit.

Further advantages and configurations of the invention may be found in the description and the appended drawings.

It is to be understood that the features mentioned above and those yet to be explained below may be used not only in the combination respectively indicated, but also in other combinations or separately, without departing from the scope of the present invention.

The invention is schematically represented with the aid of an exemplary embodiment in the drawing, and will be described in detail below with reference to the drawing.

### BRIEF DESCRIPTION OF THE DRAWING

FIG. 1 shows a structure of a possible virtual measuring arrangement such as is the basis, in one embodiment of the method according to the invention, of the simulation to be carried out in this case.

FIG. 2 shows an example of a brightness image such as is output when carrying out another embodiment of the method according to the invention.

FIG. 3 shows a flowchart of one embodiment of the method according to the invention.

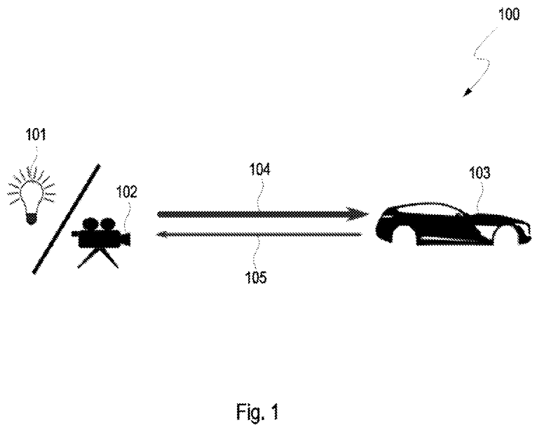

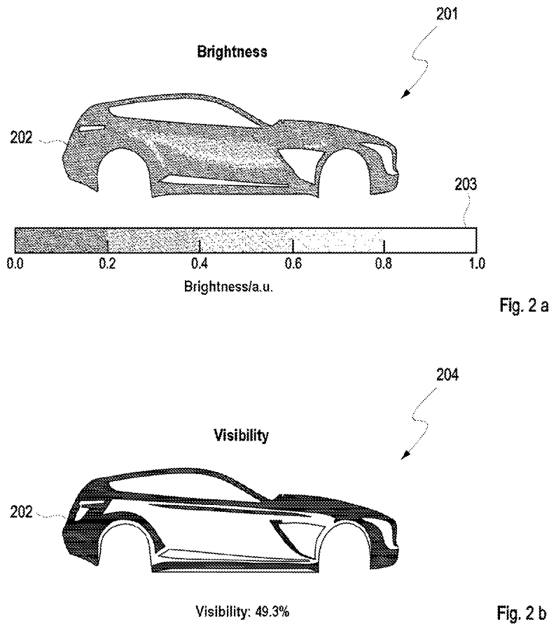

FIG. 1 shows a structure of a measuring arrangement 100 such as may be the basis, in one embodiment of the method according to the invention, of the step of simulating a propagation of the light emitted by the LiDAR sensor and reflected by the surface coated with the coating. A point light source 101, which emits light uniformly in all directions, is shown. Furthermore shown is a camera 102, which is arranged at or at least in the vicinity of the point light source 101. The point light source 101 emits laser beams 104, in general laser pulses, with a wavelength of 905 nm or 1550 nm, in the direction of a profile 103, which is in this case configured as a vehicle contour and simulates the surface coated with the coating. The light beams 105, or laser pulses, striking the vehicle contour 103 are at least partially reflected by the vehicle contour 103 and are sent back as reflected light beams 105, or laser pulses, in the direction of the camera 102. The camera 102 records the reflected light beams 105. The distance of the vehicle contour 103 from the camera 102 may in this case be varied during the simulation. The same applies for the orientation of the vehicle contour 103 relative to the camera 102. From the reflections, or reflection values, recorded in the simulation by the camera 102, a brightness image can ultimately be calculated and represented on a display unit (not shown here), as shown for example in FIG. 2.

FIG. 2 shows, in FIG. 2a, a brightness image 201 such as may be represented on a display unit as a result of the simulation method which has been carried out. The brightness of respective regions of the profile 202 is rendered, or represented, by a respective patterning/shading of the respective regions, a patterning/shading respectively being assigned to a scale value, or scale range, on a scale 203 of brightness values in the range of from 0.0 to 1.0 (a.u. in this case stands for arbitrary unit, in order to indicate a relative quantity). The respective patterning/shading may also be replaced with respective colors, in which case the scale 203 is to be selected as a corresponding color scale. In this case, the colors may for example range from dark blue for a scale value of 0.0 through green in the region of 0.5 to red at a scale value of 1.0.

FIG. 2b shows an image 204 of a visibility of the same profile 202 as shown in FIG. 2a. It can be seen in

FIG. 2b that, on the basis of the brightness, an assessment is to be made concerning which parts of the profile 202, or of the vehicle contour, are highly visible and which are substantially invisible, and consequently increase a possible risk of collision of the vehicle comprising the LiDAR sensor with another vehicle during use in autonomous driving. Such an image of the visibility is derived from the brightness image and may be represented in addition or as an alternative to the brightness image on a display unit or output unit provided according to the invention.

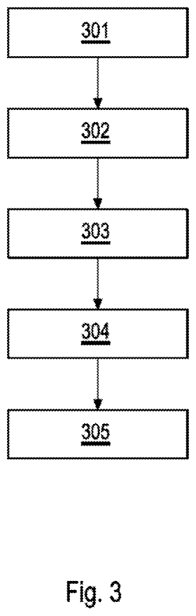

FIG. 3 shows in a schematic representation a flowchart of a sequence of one possible embodiment of the method according to the invention. In a step 301, a coating having a particular coating formulation is initially applied on a surface, preferably a sample surface in the form of a small flat face. The surface coated in this way with the coating is measured in a step 302, for example with the aid of a gonio-spectrophotometer, with respect to its reflection properties. This means that the surface is illuminated with light having an operating wavelength of a LiDAR sensor, and the light reflected by the surface coated with the coating is recorded by the gonio-spectrophotometer and evaluated. In this case, the surface is measured at a multiplicity of illumination and/or measurement angles. This means that the illumination unit, or a light beam coming from the illumination unit, preferably a laser pulse, having an operating wavelength of the LiDAR sensor is directed successively at a multiplicity of illumination angles onto the surface coated with the coating. Furthermore, the respectively reflected light beams, or the reflected laser beam or pulse, is recorded with the gonio-spectrophotometer, and its light quantity and/or intensity is determined. It is additionally conceivable to orientate the gonio-spectrophotometer successively at different measurement angles relative to the surface coated with the coating. It is conceivable to keep the illumination angle fixed and to vary the measurement angle, or conversely to vary the illumination angle and keep the measurement angle fixed.

It is also conceivable to illuminate the surface with white light which also comprises the operating wavelength of the LiDAR sensor. With the aid of the gonio-spectrometer, the intensity of the light that is reflected at the operating wavelength of the LiDAR sensor, is then measured.

During the measurement of a respective reflection of the light striking the surface coated with the coating, respective reflection values are correspondingly determined. With the aid of the reflection values, respective brightness values can in turn be determined. Accordingly, after the measurement, respective reflections or respective reflection values, and in association therewith respective brightness values, are available for respective illumination and/or measurement angles.

In a step 303, the respective measured reflections are used in order to adapt a bidirectional reflectance distribution function for the coating, with which the surface is coated, as a function of the respective illumination and/or measurement angles. This means that the parameters of the bidirectional reflectance distribution function for the coating are determined, or at least estimated, with the aid of the measured reflections or reflection values. The respective measured reflections yield a multiplicity of equations, having still unknown parameters that with a sufficient number of measured reflections, can be determined or at least estimated. A specific bidirectional reflectance distribution function with fixed parameters, which is to be indicated, is therefore obtained for the coating, with the aid of which a respective reflection can be indicated as a function of a respective illumination and/or measurement angle.

On the basis of the now adapted bidirectional reflectance distribution function, it is now possible, in a step 304, to simulate a propagation of the light emitted by the LiDAR sensor and reflected by the surface coated with the coating by means of a ray tracing application. The LiDAR sensor is in this case simulated, or modeled, as a point light source which emits light of a particular wavelength, namely an operating wavelength of the LiDAR sensor, for example 905 nm or 1550 nm, uniformly in all directions. The modeled LiDAR sensor furthermore comprises a camera which is configured in order to record light beams and determine their light quantity and/or light intensity. The surface coated with the coating is modeled during the simulation as a profile which is arranged at a variable distance with a variable orientation in front of the camera. This means that, during a respective simulation of a propagation of the light emitted by the LiDAR sensor and reflected by the surface coated with the coating, the profile may be simulated as respectively arranged in front of the camera at a different distance and/or with a different orientation. By using the adapted bidirectional reflectance distribution function, a computer graphics model is applied to the profile.

On the basis of the propagation simulated in this way, of the light emitted by the LiDAR sensor and reflected by the surface coated with the coating, in a step 305 it is now possible to output, or display on a display unit, a brightness image which shows a brightness (luminance) of the light reflected by the profile in the direction of the LiDAR sensor while taking into account the adapted bidirectional reflectance distribution function. In this case, the brightness image may explicitly be displayed as light on a display unit, or respective values of the brightness may be indicated for the coating and assigned thereto. In general, the described method is carried out for a multiplicity of different coatings and associated coating formulations, so that ultimately a comparison may be carried out between the coatings with the aid of the respective brightness images, and that coating, or the associated coating formulation, may be selected whose brightness image implies that the coating is most highly visible for a LiDAR sensor and therefore an object coated with the coating is most highly detectable for a LiDAR sensor.

1. A method for simulating a visibility of a coating applied on a surface for a LiDAR sensor, which comprises at least the following steps:
applying the coating on the surface (301);
measuring a respective reflection of light having an operating wavelength of the LiDAR sensor from the surface coated with the coating at a multiplicity of illumination and/or measurement angles (302);
adapting a bidirectional reflectance distribution function for the coating as a function of the respective illumination and/or measurement angle to the respective measured reflections (303);
simulating a propagation of the light emitted by the LiDAR sensor and reflected by the surface coated with the coating on the basis of the adapted bidirectional reflectance distribution function by means of a ray tracing application (304), the LiDAR sensor being simulated as a unit comprising a point light source (101) and a camera (102), and the surface coated with the coating being simulated as a profile (103, 202) which is arranged at a variable distance with a variable orientation in front of the camera (102); and
outputting a brightness image (201), which shows a brightness of the light reflected by the profile (103, 202) in the direction of the LiDAR sensor while taking into account the adapted bidirectional reflectance distribution function (305).

2. The method as claimed in claim 1, wherein how much light is reflected by different regions of the profile (103, 202) simulating the surface is determined by means of the brightness image (201) which has been output.

3. The method as claimed in claim 1, wherein the brightness threshold value, which is defined by a reflected brightness of a reference template with a diffuse reflection of 10%, is applied to the brightness image (201).

4. The method as claimed in claim 1, wherein a visible region of the profile (103, 202) simulating the surface is quantified as a fraction of a maximum visible region of the profile (103, 202) simulating the surface for a current orientation or setting of the profile (103, 202) relative to the simulated LiDAR sensor.

5. The method as claimed in claim 1, wherein the bidirectional reflectance distribution function for the coating is formed from a weighted diffuse Lambert term and a Cook-Torrance illumination model term having at least one specular lobe.

6. The method as claimed in claim 1, wherein parameters of the bidirectional reflectance distribution function are optimized with respect to a cost function during the adaptation of the bidirectional reflectance distribution function for the coating.

7. The method as claimed in claim 6, wherein the cost function is formed on the basis of a penalty term and a sum of squared differences between the measured respective reflections and respective reflections simulated on the basis of the bidirectional reflectance distribution function.

8. The method as claimed in claim 6, wherein the parameters of the bidirectional reflectance distribution function are optimized with a nonlinear optimization method.

9. The method as claimed in claim 1, wherein the profile (103, 202) simulating the surface is selected as a vehicle contour.

10. The method as claimed in claim 1, which is carried out for a multiplicity of coating formulations, wherein the output respective brightness images (201) for the different coating formulations are compared with one another and that coating formulation which is most highly visible for the LiDAR sensor is selected from the multiplicity of coating formulations.

11. A device for simulating a visibility of a coating applied on a surface for a LiDAR sensor, which comprises at least:
an application unit for applying the coating on the surface;
a measuring arrangement for measuring a respective reflection of light having an operating wavelength of the LiDAR sensor from the surface coated with the coating at a multiplicity of illumination and/or measurement angles;
a computer unit for adapting a bidirectional reflectance distribution function for the coating as a function of the respective illumination and/or measurement angle to the respective measured reflections;
a simulation unit for simulating a propagation of the light emitted by the LiDAR sensor and reflected by the surface coated with the coating on the basis of the adapted bidirectional reflectance distribution function by means of a ray tracing application, the LiDAR sensor being simulated as a unit comprising a point light source (101) and a camera (102), and the surface coated with the coating being simulated as a profile (103, 202) which is arranged at a variable distance with a variable orientation in front of the camera; and
an output unit for outputting a brightness image (201), which shows a brightness of the light reflected by the profile (103, 202) in the direction of the LiDAR sensor while taking into account the adapted bidirectional reflectance distribution function.

12. The device as claimed in claim 11, wherein the measuring unit comprises at least one goniospectrometer.

13. The device as claimed in claim 11, which is configured for carrying out a method for simulating a visibility of a coating applied on a surface for a LiDAR sensor, which comprises at least the following steps:
applying the coating on the surface (301);
measuring a respective reflection of light having an operating wavelength of the LiDAR sensor from the surface coated with the coating at a multiplicity of illumination and/or measurement angles (302);
adapting a bidirectional reflectance distribution function for the coating as a function of the respective illumination and/or measurement angle to the respective measured reflections (303);
simulating a propagation of the light emitted by the LiDAR sensor and reflected by the surface coated with the coating on the basis of the adapted bidirectional reflectance distribution function by means of a ray tracing application (304), the LiDAR sensor being simulated as a unit comprising a point light source (101) and a camera (102), and the surface coated with the coating being simulated as a profile (103, 202) which is arranged at a variable distance with a variable orientation in front of the camera (102); and
outputting a brightness image (201), which shows a brightness of the light reflected by the profile (103, 202) in the direction of the LiDAR sensor while taking into account the adapted bidirectional reflectance distribution function (305).

14. A computer program product comprising a computer program, having program code means which are configured in order to carry out at least the computer-assisted steps of the method as claimed in claim 1 when the computer program is run on a computer unit.

15. The method as claimed in claim 6, wherein the parameters of the bidirectional reflectance distribution function are optimized with the Nelder-Mead downhill simplex method.
